(19) United States
(12) Patent Application Publication
(10) Pub. No.: US 2025/0377396 A1
(43) Pub. Date: Dec. 11, 2025

(54) CROSSTALK MEASURING METHOD AND CROSSTALK MEASURING PROBE

(71) Applicant: SUMITOMO ELECTRIC INDUSTRIES, LTD., Osaka (JP)

(72) Inventors: Shun IGARASHI, Osaka (JP); Hiroshi UEDA, Osaka (JP); Suguru YAMAGISHI, Osaka (JP); Ichiro KUWAYAMA, Osaka (JP)

(73) Assignee: SUMITOMO ELECTRIC INDUSTRIES, LTD., Osaka (JP)

(21) Appl. No.: 18/872,807

(22) PCT Filed: May 2, 2023
(86) PCT No.: PCT/JP2023/017121

§ 371 Date: Dec. 7, 2024

(30) Foreign Application Priority Data
Jun. 14, 2022 (JP) 2022-095734

(51) Int. Cl. G01R 29/26

(52) U.S. Cl. CPC G01R 29/26

(57) ABSTRACT

A crosstalk measuring method includes: preparing a printed wiring board having a first signal pattern and a second signal pattern arranged side by side at an interval in a first direction and extending in a second direction orthogonal to the first direction, and a ground pattern disposed between the first signal pattern and the second signal pattern in the first direction and extending in the second direction; preparing a probe having a first pin, a second pin, and a shield plate that is made of a conductive material; and measuring crosstalk between the first signal pattern and the second signal pattern. Each of the first pin and the second pin has a distal end and a proximal end opposite to the distal end.

### TECHNICAL FIELD

The present disclosure relates to a crosstalk measuring method and a crosstalk measuring probe. The present application claims a priority based on Japanese Patent Application No. 2022-095734 filed on Jun. 14, 2022, the entire content of which is incorporated herein by reference.

### BACKGROUND ART

For example, Japanese Patent Laying-Open No. 2019-62114 (PTL 1) discloses a printed wiring board. The printed wiring board disclosed in PTL 1 includes a base film, a first signal pattern, a second signal pattern, and a ground pattern. The base film has a main surface. The first signal pattern, the second signal pattern, and the ground pattern are disposed on the main surface of the base film.

The first signal pattern and the second signal pattern are arranged side by side at an interval in a first direction and extend in a second direction orthogonal to the first direction. The ground pattern is disposed between the first signal pattern and the second signal pattern in the first direction. In the printed wiring board disclosed in PTL 1, crosstalk may occur between a signal flowing through the first signal pattern and a signal flowing through the second signal pattern.

### CITATION LIST

### Patent Literature

PTL 1: Japanese Patent Laying-Open No. 2019-62114

### SUMMARY OF INVENTION

A crosstalk measuring method according to the present disclosure includes: preparing a printed wiring board having a first signal pattern and a second signal pattern arranged side by side at an interval in a first direction, the first signal pattern and the second signal pattern extending in a second direction orthogonal to the first direction, and a ground pattern disposed between the first signal pattern and the second signal pattern in the first direction and extending in the second direction; preparing a probe having a first pin, a second pin, and a shield plate that is made of a conductive material; and measuring crosstalk between the first signal pattern and the second signal pattern. Each of the first pin and the second pin has a distal end and a proximal end opposite to the distal end. The distal end of the first pin and the distal end of the second pin are in contact with the first signal pattern and the second signal pattern, respectively. The shield plate extends along a plane orthogonal to the first direction, and has an upper end and a lower end opposite to the upper end in a third direction orthogonal to the first direction and the second direction, the lower end being in contact with the ground pattern. The shield plate is located between the first pin and the second pin in the first direction. The shield plate has a thickness greater than a skin depth for an electromagnetic wave equal in frequency to signals flowing through the first signal pattern and the second signal pattern.

### BRIEF DESCRIPTION OF DRAWINGS

FIG. 1 is a plan view of a printed wiring board 10.

FIG. 2 is a cross-sectional view taken along II-II in FIG. 1.

FIG. 3 is a perspective view of a crosstalk measuring probe 20.

FIG. 4 is a side view of crosstalk measuring probe 20.

FIG. 5 is a flowchart of a crosstalk measuring method according to an embodiment.

FIG. 6 is a plan view of a printed wiring board 10 according to a modification.

FIG. 7 is a side view of a crosstalk measuring probe 20 according to a first modification.

FIG. 8 is a side view of a crosstalk measuring probe 20 according to a second modification.

FIG. 9 is a perspective view of a crosstalk measuring probe 20 according to a third modification.

FIG. 10 is a side view of crosstalk measuring probe 20 according to the third modification.

FIG. 11 is a graph showing a relation between: a frequency of each of differential signals flowing through signal patterns 12a and 12b; and a crosstalk amount of each of differential components to signal patterns 13a and 13b.

### DETAILED DESCRIPTION

### Problem to be Solved by the Present Disclosure

In order to measure the crosstalk as described above, a crosstalk measuring probe is used. The crosstalk measuring probe has a first pin and a second pin. Each of the first pin and the second pin has a distal end. The distal end of the first pin and the distal end of the second pin are brought into contact with a first signal pattern and a second signal pattern, respectively.

However, when such a crosstalk measuring probe is used to measure the crosstalk between a signal flowing through the first signal pattern and a signal flowing through the second signal pattern, crosstalk may occur between the first pin and the second pin, which may decrease the accuracy in measuring the crosstalk between the signal flowing through the first signal pattern and the signal flowing through the second signal pattern.

The present disclosure has been made in view of the problems of the prior art as described above. More specifically, the present disclosure provides a crosstalk measuring method allowing for an improved accuracy in measuring crosstalk.

### Advantageous Effect of the Present Disclosure

According to the crosstalk measuring method in the present disclosure, the accuracy in measuring crosstalk can be improved.

### Description of Embodiments of the Present Disclosure

Embodiments of the present disclosure will be first described.

(1) A crosstalk measuring method according to an embodiment includes: preparing a printed wiring board having a first signal pattern and a second signal pattern arranged side by side at an interval in a first direction, the first signal pattern and the second signal pattern extending in a second direction orthogonal to the first direction, and a ground pattern disposed between the first signal pattern and the second signal pattern in the first direction and extending in the second direction; preparing a probe having a first pin, a second pin, and a shield plate that is made of a conductive material; and measuring crosstalk between the first signal pattern and the second signal pattern. Each of the first pin and the second pin has a distal end and a proximal end opposite to the distal end. The distal end of the first pin and the distal end of the second pin are in contact with the first signal pattern and the second signal pattern, respectively. The shield plate extends along a plane orthogonal to the first direction, and has an upper end and a lower end opposite to the upper end in a third direction orthogonal to the first direction and the second direction, the lower end being in contact with the ground pattern. The shield plate is located between the first pin and the second pin in the first direction. The shield plate has a thickness greater than a skin depth for an electromagnetic wave equal in frequency to signals flowing through the first signal pattern and the second signal pattern.

According to the crosstalk measuring method in the above (1), the accuracy in measuring the crosstalk can be improved.

(2) In the crosstalk measuring method according to the above (1), the upper end may be located above the proximal end of the first pin and the proximal end of the second pin in the third direction.

According to the crosstalk measuring method in the above (2), the accuracy in measuring the crosstalk can be further improved.

(3) In the crosstalk measuring method according to the above (1) or (2), the shield plate may have a rear end and a front end opposite to the rear end in the second direction. The front end may be located to protrude in the second direction by 0.5 mm or more and 5 mm or less from the distal end of the first pin and the distal end of the second pin.

According to the crosstalk measuring method in the above (3), the accuracy in measuring the crosstalk can be further improved.

(4) In the crosstalk measuring method according to the above (1) to (3), the shield plate may have a plurality of protrusions at the lower end, the plurality of protrusions being arranged at intervals in the second direction and brought into contact with the ground pattern. A pitch between two adjacent protrusions among the plurality of protrusions may be 0.4 mm or less.

According to the crosstalk measuring method in the above (4), an electrical contact between the shield plate and the ground pattern can be easily accomplished while improving the accuracy in measuring the crosstalk.

(5) In the crosstalk measuring method according to the above (4), each of the plurality of protrusions may have a height of 0.5 mm or less.

According to the crosstalk measuring method in the above (5), an electrical contact between the shield plate and the ground pattern can be easily accomplished while improving the accuracy in measuring the crosstalk.

(6) A crosstalk measuring probe according to an embodiment includes: a first pin and a second pin; and a shield plate made of a conductive material. Each of the first pin and the second pin has a distal end and a proximal end opposite to the distal end. The distal end of the first pin and the distal end of the second pin are spaced apart from each other in a first direction. The shield plate extends along a plane orthogonal to the first direction and is located between the first pin and the second pin in the first direction. The shield plate may have a thickness greater than a skin depth for an electromagnetic wave equal in frequency to signals flowing through the first pin and the second pin.

According to the crosstalk measuring probe in the above (6), the accuracy in measuring the crosstalk can be improved.

(7) In the crosstalk measuring probe according to the above (6), the shield plate may have a rear end and a front end opposite to the rear end in a second direction orthogonal to the first direction. The front end may be located to protrude in the second direction by 0.5 mm or more and 5 mm or less from the distal end of the first pin and the distal end of the second pin.

According to the crosstalk measuring probe in the above (7), the accuracy in measuring the crosstalk can be further improved.

(8) In the crosstalk measuring probe according to the above (7), the shield plate may have an upper end and a lower end opposite to the upper end in a third direction orthogonal to the first direction and the second direction, and may have a plurality of protrusions at the lower end, the plurality of protrusions being arranged at intervals in the second direction.

According to the crosstalk measuring probe in the above (8), an electrical contact between the shield plate and the ground pattern can be easily accomplished.

(9) In the crosstalk measuring probe according to the above (8), a pitch between two adjacent protrusions among the plurality of protrusions may be 0.4 mm or less.

According to the crosstalk measuring probe in the above (9), an electrical contact between the shield plate and the ground pattern can be easily accomplished while improving the accuracy in measuring the crosstalk.

(10) In the crosstalk measuring probe according to the above (8) or (9), each of the plurality of protrusions may have a height of 0.5 mm or less.

According to the crosstalk measuring probe in the above (10), an electrical contact between the shield plate and the ground pattern can be easily accomplished while improving the accuracy in measuring the crosstalk.

(11) In the crosstalk measuring probe according to the above (6) or (7), the shield plate may have an upper end and a lower end opposite to the upper end in a third direction orthogonal to the first direction and the second direction. The upper end may be located above the proximal end of the first pin and the proximal end of the second pin in the third direction.

According to the crosstalk measuring probe in the above (11), the accuracy in measuring the crosstalk can be further improved.

### Details of Embodiments of the Present Disclosure

Then, embodiments of the present disclosure will be described in detail with reference to the accompanying drawings. In the accompanying drawings described below, the same or corresponding portions are denoted by the same reference characters, and the same description will not be repeated. A printed wiring board to be subjected to crosstalk measurement is referred to as a printed wiring board 10. The crosstalk measuring probe according to an embodiment is referred to as a crosstalk measuring probe 20.

### (Configuration of Printed Wiring Board 10)

The following describes a configuration of printed wiring board 10.

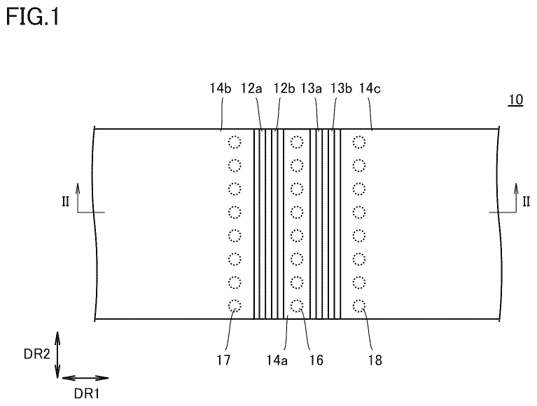

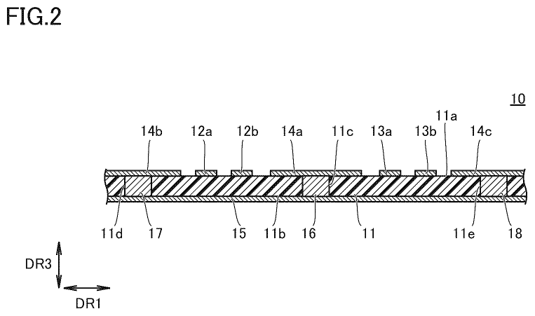

FIG. 1 is a plan view of printed wiring board 10. FIG. 2 is a cross-sectional view taken along II-II in FIG. 1. As shown in FIGS. 1 and 2, printed wiring board 10 includes a base film 11, signal patterns 12a, 12b, 13a, and 13b, ground patterns 14a, 14b, 14c, and 15, and a conductor layer 16.

Base film 11 has a first surface 11a and a second surface 11b. First surface 11a and second surface 11b are end surfaces of base film 11 in its thickness direction. Second surface 11b is opposite to first surface 11a. Base film 11 is made, for example, of a fluorine resin. However, base film 11 may be made of a material other than the fluorine resin.

Signal patterns 12a, 12b, 13a, and 13b are disposed on first surface 11a. Signal patterns 12a, 12b, 13a, and 13b are arranged side by side at intervals in a first direction DR1. First direction DR1 is one of directions orthogonal to a direction normal to first surface 11a.

Signal patterns 12a, 12b, 13a, and 13b extend in a second direction DR2. Second direction DR2 is orthogonal to first direction DR1.

Signal patterns 12b and 13a are located between signal patterns 12a and 13b in first direction DR1. Signal pattern 12b is located between signal patterns 12a and 13a in first direction DR1. In other words, signal patterns 12a, 12b, 13a, and 13b are arranged side by side in this order from one side to the other side in first direction DR1.

The signal flowing through signal pattern 12a is opposite in phase to the signal flowing through signal pattern 12b. The signal flowing through signal pattern 13a is opposite in phase to the signal flowing through signal pattern 13b. In other words, signal patterns 12a and 12b constitute a pair of differential signal lines, and signal patterns 13a and 13b constitute a pair of differential signal lines.

Ground patterns 14a, 14b, and 14c are disposed on first surface 11a. Ground pattern 14a is disposed between signal patterns 12b and 13a so as to be spaced apart from signal patterns 12b and 13a in first direction DR1.

Ground pattern 14b is adjacent to signal pattern 12a from the side opposite to signal pattern 12b so as to be spaced apart from signal pattern 12a in first direction DR1. Ground pattern 14c is adjacent to signal pattern 13b from the side opposite to signal pattern 13a so as to be spaced apart from signal pattern 13b in first direction DR1.

Ground pattern 15 is disposed on second surface 11b. Ground pattern 15 is disposed over the entire surface of second surface 11b. Ground pattern 15 serves as a ground potential.

Base film 11 is provided with a plurality of through holes 11c. The plurality of through holes 11c overlap with ground pattern 14a in a plan view. The plurality of through holes 11c are located side by side at intervals in second direction DR2. Each through hole 11c is, for example, circular in a plan view. Through hole 11c penetrates base film 11 in its thickness direction. Conductor layer 16 is provided inside through hole 11c. Thereby, ground pattern 14a is electrically connected to ground pattern 15 and serves as a ground potential.

Base film 11 may be further provided with a plurality of through holes 11d and a plurality of through holes 11e. The plurality of through holes 11d overlap with ground pattern 14b in a plan view and are located side by side at intervals in second direction DR2. The plurality of through holes 11e overlap with ground pattern 14c in a plan view and are located side by side at intervals in second direction DR2. Through holes 11d and 11e are, for example, circular in a plan view and penetrate base film 11 in its thickness direction. Conductor layers 17 and 18 are provided inside through holes 11d and 11e, respectively. Thereby, ground patterns 14b and 14c are electrically connected to ground pattern 15 and each serve as a ground potential.

Note that each of signal patterns 12a, 12b, 13a, and 13b, ground patterns 14a, 14b, 14c, and 15, and conductor layers 16, 17, and 18 is made, for example, of copper. However, each of signal patterns 12a, 12b, 13a, and 13b, ground patterns 14a, 14b, 14c, and 15, and conductor layers 16, 17, and 18 may be made of a conductive material other than copper.

### (Configuration of Crosstalk Measuring Probe 20)

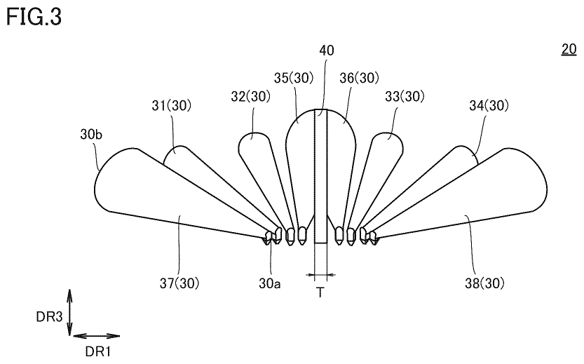

FIG. 3 is a perspective view of crosstalk measuring probe 20. As shown in FIG. 3, crosstalk measuring probe 20 includes a plurality of pins 30 and a shield plate 40.

Each pin 30 has a distal end 30a and a proximal end 30b. Proximal end 30b is opposite to distal end 30a. The direction orthogonal to first direction DR1 and second direction DR2 is defined as a third direction DR3. Note that third direction DR3 corresponds to the direction normal to first surface 11a. Pin 30 extends to be inclined with respect to a plane orthogonal to third direction DR3 such that proximal end 30b is located above distal end 30a in third direction DR3. Distal ends 30a of the plurality of pins 30 are arranged at intervals in first direction DR1.

Pin 30 whose distal end 30a contacts signal pattern 12a is referred to as a pin 31, and pin 30 whose distal end 30a contacts signal pattern 12b is referred to as a pin 32. Pin 30 whose distal end 30a contacts signal pattern 13a is referred to as a pin 33, and pin 30 whose distal end 30a contacts signal pattern 13b is referred to as a pin 34.

Pins 30 whose distal ends 30a contact ground pattern 14a are referred to as pins 35 and 36. Note that pin 35 is closer to pin 32 than pin 36 is. Pin 30 whose distal end 30a contacts ground pattern 14b is referred to as a pin 37, and pin 30 whose distal end 30a contacts ground pattern 14c is referred to as a pin 38.

Although not shown, proximal ends 30b of pins 31, 32, 33, and 34 are connected to a central conductor of a coaxial cable. The coaxial cable is connected to a high-frequency signal source. Pins 35, 36, 37, and 38 are connected to an outer conductor of the coaxial cable. The outer conductor of the coaxial cable desirably serves as a ground potential.

Shield plate 40 is made of a conductive material. Shield plate 40 is made, for example, of aluminum, copper, stainless steel, chromium, beryllium copper, or phosphor bronze. However, shield plate 40 may be made of a conductive material other than these materials. The surface of shield plate 40 may be plated with gold, or may be coated with a magnetic material. Shield plate 40 extends along a plane orthogonal to first direction DR1. Shield plate 40 is disposed between pins 32 and 33 in first direction DR1. More specifically, shield plate 40 is disposed between pins 35 and 36 in first direction DR1. Shield plate 40 is fixed, for example, to pins 35 and 36. This fixing is done, for example, by soldering.

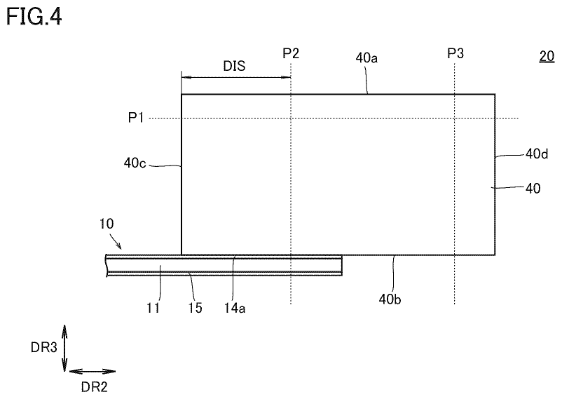

FIG. 4 is a side view of crosstalk measuring probe 20. FIG. 4 does not show the plurality of pins 30. FIG. 4 also shows printed wiring board 10. As shown in FIG. 4, shield plate 40 is a plate-shaped member having a rectangular shape in a side view.

Shield plate 40 has an upper end 40a and a lower end 40b in third direction DR3. Lower end 40b is opposite to upper end 40a. Shield plate 40 is in contact with ground pattern 14a at lower end 40b. Thus, shield plate 40 serves as a ground potential. Each of the positions of proximal ends 30b of pins 32 and 33 in third direction DR3 is referred to as a position P1. Upper end 40a is preferably located above position P1 in third direction DR3.

Shield plate 40 has a front end 40c and a rear end 40d in second direction DR2. Rear end 40d is opposite to front end 40c. Each of the positions of distal ends 30a of pins 32 and 33 in second direction DR2 is referred to as a position P2. Each of the positions of proximal ends 30b of pins 32 and 33 in second direction DR2 is referred to as a position P3. Front end 40c is located to protrude from position P2 in second direction DR2. Rear end 40d is located to protrude from position P3 in second direction DR2.

The distance in second direction DR2 between position P2 and front end 40c is defined as a distance DIS. Distance DIS is preferably 0.5 mm or more and 5 mm or less. The thickness of shield plate 40 is defined as a thickness T (see FIG. 3). Thickness T is preferably greater than the skin depth for electromagnetic waves emitted from pins 31, 32, 33, and 34.

Note that the skin depth varies depending on the magnetic permeability and the electrical conductivity of the material forming shield plate 40 in addition to the frequencies of the electromagnetic waves emitted from pins 31, 32, 33, and 34. The frequencies of the electromagnetic waves emitted from pins 31, 32, 33, and 34 are equal to the frequencies of the signals flowing through signal patterns 12a, 12b, 13a, and 13b (the frequencies of the signals flowing through pins 31, 32, 33, and 34).

### Crosstalk Measuring Method According to Embodiment

The following describes a crosstalk measuring method according to an embodiment.

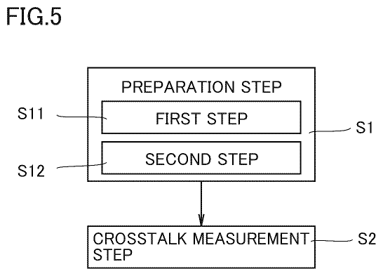

FIG. 5 is a flowchart of a crosstalk measuring method according to an embodiment. As shown in FIG. 5, the crosstalk measuring method according to the embodiment includes a preparation step S1 and a crosstalk measurement step S2. Preparation step S1 includes a first step S11 and a second step S12.

In first step S11, printed wiring board 10 is prepared. In second step S12, crosstalk measuring probe 20 is prepared.

Crosstalk measurement step S2 is performed after preparation step S1. In crosstalk measurement step S2, first, distal end 30a of pin 31 and distal end 30a of pin 32 are brought into contact with the end of signal pattern 12a and the end of signal pattern 12b, respectively, and distal end 30a of pin 33 and distal end 30a of pin 34 are brought into contact with the end of signal pattern 13a and the end of signal pattern 13b, respectively. At this time, distal end 30a of pin 35 and distal end 30a of pin 36 are brought into contact with ground pattern 14a, and distal end 30a of pin 37 and distal end 30a of pin 38 are brought into contact with ground pattern 14b and ground pattern 14c, respectively.

In crosstalk measurement step S2, secondly, a differential signal is caused to flow through each of pins 31 and 32. As a result, while differential signals flow through signal patterns 12a and 12b, some of the differential signals are transferred to signal patterns 13a and 13b, and pins 33 and 34. In this state, the crosstalk is measured by determining the ratio between: the strengths of the signals input to pins 31 and 32; and the strengths of the signals output from pins 33 and 34.

### (Modifications)

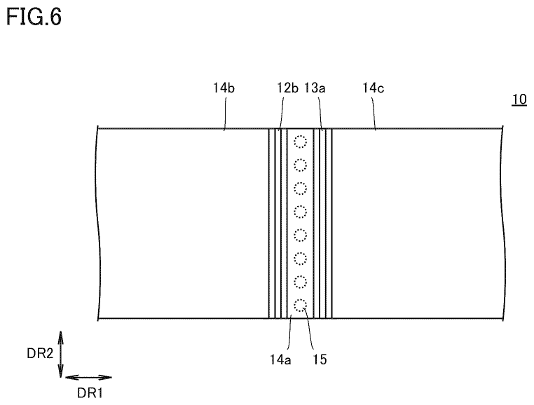

FIG. 6 is a plan view of printed wiring board 10 according to a modification. As shown in FIG. 6, printed wiring board 10 may not have signal patterns 12a and 13b. In this case, each of signal patterns 12b and 13a is a single-ended signal line. In this case, crosstalk measuring probe 20 does not necessarily have to include pins 31, 34, 37, and 38.

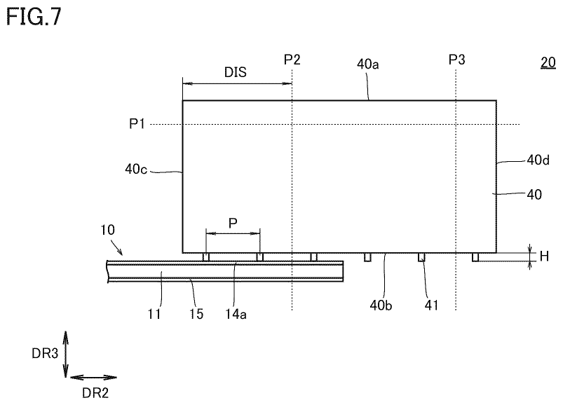

FIG. 7 is a side view of crosstalk measuring probe 20 according to the first modification. FIG. 7 does not show the plurality of pins 30. FIG. 7 also shows printed wiring board 10. As shown in FIG. 7, shield plate 40 may have a plurality of protrusions 41 formed on lower end 40b and may be brought into contact with ground pattern 14a at the plurality of protrusions 41.

The plurality of protrusions 41 are arranged at intervals in second direction DR2. A pitch between two adjacent protrusions 41 is defined as a pitch P. Pitch P is preferably 0.4 mm or less. The height of protrusion 41 is defined as a height H. Height H is preferably 0.5 mm or less.

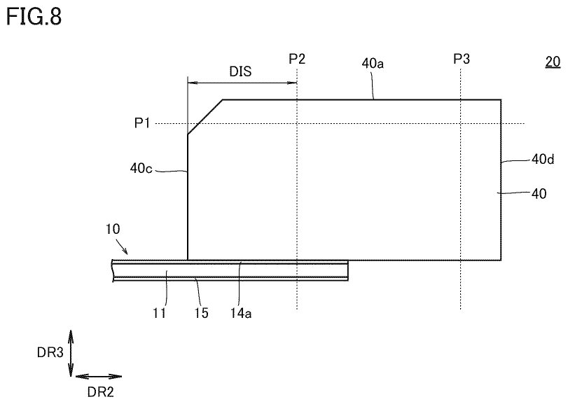

FIG. 8 is a side view of crosstalk measuring probe 20 according to the second modification. FIG. 8 does not show the plurality of pins 30. FIG. 8 also shows printed wiring board 10. As shown in FIG. 8, shield plate 40 may not be rectangular in a side view. For example, shield plate 40 may be shaped to have a chamfered corner between sides on the front end 40c side and the upper end 40a side in a side view.

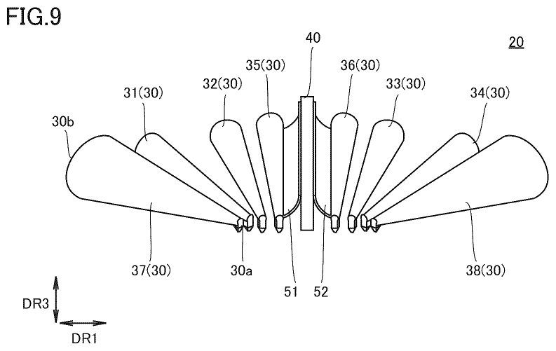

FIG. 9 is a perspective view of crosstalk measuring probe 20 according to the third modification. As shown in FIG. 9, crosstalk measuring probe 20 may include spring members 51 and 52. Spring members 51 and 52 are attached to pins 35 and 36, respectively. Shield plate 40 is sandwiched between spring members 51 and 52, and is slidable between spring members 51 and 52. Shield plate 40 is biased toward printed wiring board 10 by spring members 51 and 52.

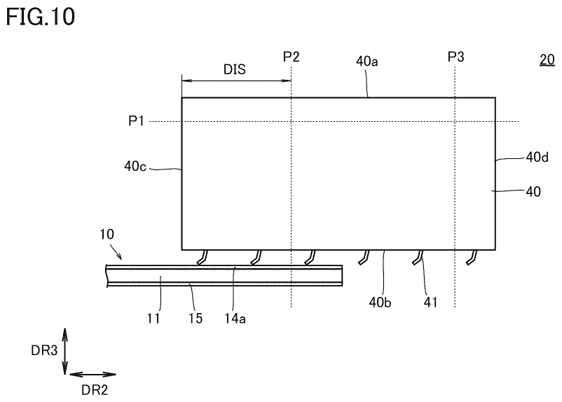

FIG. 10 is a side view of crosstalk measuring probe 20 according to the third modification. FIG. 10 does not show the plurality of pins 30. FIG. 10 also shows printed wiring board 10. As shown in FIG. 10, each protrusion 41 may have spring characteristics. In other words, each protrusion 41 may be configured to be elastically deformed as it comes into contact with ground pattern 14b.

### (Effects of Crosstalk Measuring Method According to Embodiment)

The following describes the effects of the crosstalk measuring method according to the embodiment.

When the crosstalk between signal patterns 12b and 13a is measured, a high-frequency signal flows through pins 32 and 33, and accordingly, crosstalk may occur between pins 32 and 33. Such crosstalk occurring between pins 32 and 33 prevents accurate measurement of the crosstalk between signal patterns 12b and 13a.

Crosstalk measuring probe 20 includes shield plate 40 that is disposed between pins 32 and 33 in second direction DR2 and that is in contact with ground pattern 14a at lower end 40b (i.e., serves as a ground potential). Thus, the electromagnetic waves emitted from pins 32 and 33 are shielded by shield plate 40, and crosstalk between pins 32 and 33 is suppressed. In this way, according to the crosstalk measuring method of the embodiment, crosstalk measuring probe 20 is used, so that the accuracy in measuring the crosstalk between signal patterns 12b and 13a is improved.

When upper end 40a is located above position P1, the electromagnetic waves emitted from pins 32 and 33 less easily bypass shield plate 40. Thus, in this case, the occurrence of crosstalk between pins 32 and 33, and consequently, the occurrence of crosstalk between signal patterns 12b and 13a are further suppressed.

As distance DIS is longer, the electromagnetic waves emitted from pins 32 and 33 less easily bypass shield plate 40, so that the crosstalk between pins 32 and 33 is more easily suppressed. However, as distance DIS is longer, the crosstalk between signal patterns 12b and 13a that should essentially not be suppressed is suppressed more, so that the accuracy in measuring the crosstalk between signal patterns 12b and 13a decreases accordingly. Thus, by setting distance DIS to be 0.5 mm or more and 5 mm or less, the crosstalk between signal patterns 12b and 13a can be more accurately measured.

When shield plate 40 has the plurality of protrusions 41 at lower end 40b, a contact between shield plate 40 and ground pattern 14a is easily accomplished. When pitch P is too large or height H is too high, the electromagnetic waves emitted from pins 32 and 33 through between two adjacent protrusions 41 more easily bypass shield plate 40. Thus, when pitch P is 0.4 mm or less and height H is 0.5 mm or less, an electrical contact between shield plate 40 and ground pattern 14a can be easily accomplished while improving the accuracy in measuring the crosstalk. When each protrusion 41 has spring characteristics, an electrical contact with ground pattern 14a can be more easily accomplished.

In the case where crosstalk measuring probe 20 has spring members 51 and 52, and shield plate 40 is slidably sandwiched between spring members 51 and 52, even if shield plate 40 is longer in second direction DR2, sliding this shield plate 40 easily accomplishes a uniform electrical contact between shield plate 40 and ground pattern 14a.

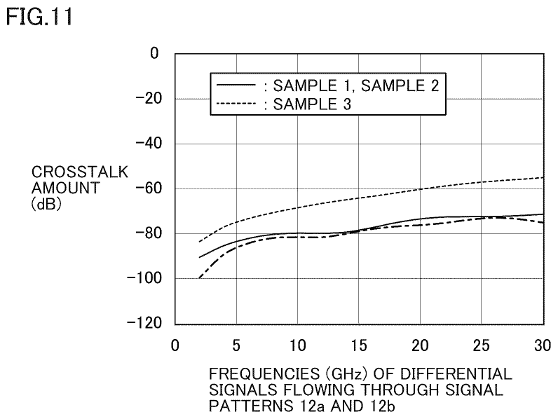

FIG. 11 is a graph showing the relation between: a frequency of each of differential signals flowing through signal patterns 12a and 12b; and a crosstalk amount of each of differential components to signal patterns 13a and 13b. The horizontal axis in FIG. 11 represents the frequency (unit: GHz) of each of the signals flowing through signal patterns 12a and 12b. The vertical axis in FIG. 11 represents the crosstalk amount (unit: dB) of each of the differential components to signal patterns 13a and 13b. As shown in FIG. 11, samples 1, 2, and 3 were subjected to a crosstalk analysis.

In each of samples 1 and 2, the crosstalk between signal patterns 12b and 13a was measured using crosstalk measuring probe 20. In sample 1, shield plate 40 did not have a plurality of protrusions 41 at lower end 40b. On the other hand, in sample 2, shield plate 40 had a plurality of protrusions 41 at lower end 40b. In sample 2, pitch P was 0.4 mm, and height H was 0.1 mm. In sample 3, a crosstalk measuring probe not having shield plate 40 was used.

In each of samples 1 and 2, thickness T was 0.1 mm, and shield plate 40 was made of copper. In each of samples 1 and 2, the height of shield plate 40 was 1.1 mm. In each of samples 1 and 2, the width of shield plate 40 in second direction DR2 was 2.4 mm. In each of samples 1 and 2, upper end 40a was located above proximal ends 30b of pins 32 and 33 in third direction DR3, and front end 40c and rear end 40d were located to protrude from position P2 and position P3, respectively, in second direction DR2. In each of samples 1 and 2, distance DIS was 1.0 mm.

In printed wiring board 10 subjected to the crosstalk analysis, base film 11 was made of a fluorine resin. In printed wiring board 10 subjected to the crosstalk analysis, base film 11 had a thickness of 0.057 mm.

In printed wiring board 10 subjected to the crosstalk analysis, signal patterns 12a, 12b, 13a, and 13b, and ground patterns 14a, 14b, 14c, and 15 each had a thicknesses of 0.012 mm. In printed wiring board 10 subjected to the crosstalk analysis, signal patterns 12a, 12b, 13a, and 13b, and ground patterns 14a, 14b, 14c, and 15 each were made of copper.

In the printed wiring board subjected to the crosstalk analysis, signal patterns 12a, 12b, 13a, and 13b each had a width of 0.068 mm in first direction DR1, and ground pattern 14a had a width of 0.368 mm in first direction DR1. In printed wiring board 10 subjected to the crosstalk analysis, each of the distance between signal patterns 12a and 12b, the distance between signal patterns 13a and 13b, the distance between signal pattern 12b and ground pattern 14a, and the distance between signal pattern 13a and ground pattern 14a was 0.032 mm.

As shown in FIG. 8, in sample 3, the crosstalk between pins 32 and 33 was large, and thus, the crosstalk between signal patterns 12b and 13a could be measured only up to about-60 dB. On the other hand, in each of samples 1 and 2, the crosstalk larger than this could be measured. Based on this, the simulation also revealed that the crosstalk measuring method according to the embodiment allowed for an improved accuracy in measuring the crosstalk between signal patterns 12b and 13a.

The curve showing the result of the crosstalk analysis for sample 2 substantially overlapped with the curve showing the result of the crosstalk analysis for sample 1. Based on this, the simulation also revealed that pitch P of 0.4 mm or less and height H of 0.5 mm or less made it possible to easily accomplish an electrical contact between shield plate 40 and ground pattern 14a while improving the accuracy in measuring the crosstalk.

It should be understood that the embodiments disclosed herein are illustrative and non-restrictive in every respect. The scope of the present invention is defined by the terms of the claims, rather than the embodiments described above, and is intended to include any modifications within the meaning and scope equivalent to the terms of the claims.

### REFERENCE SIGNS LIST

10 printed wiring board, 11 base film, 11a first surface, 11b second surface, 11c through hole, 12a, 12b, 13a, 13b signal pattern, 14a, 14b, 14c, 15 ground pattern, 16, 17, 18 conductor layer, 20 crosstalk measuring probe, 30, 31, 32, 33, 34, 36, 37, 38 pin, 30a distal end, 30b proximal end, 40 shield plate, 40a upper end, 40b lower end, 40c front end, 40d rear end, 41 protrusion, 51, 52 spring member, DIS distance, DR1 first direction, DR2 second direction, DR3 third direction, H height, P1, P2, P3 position, S1 preparation step, S2 crosstalk measurement step, S11 first step, S12 second step, P pitch, T thickness.

1. A crosstalk measuring method comprising:
preparing a printed wiring board having
a first signal pattern and a second signal pattern arranged side by side at an interval in a first direction, the first signal pattern and the second signal pattern extending in a second direction orthogonal to the first direction, and
a ground pattern disposed between the first signal pattern and the second signal pattern in the first direction and extending in the second direction;
preparing a probe having a first pin, a second pin, and a shield plate that is made of a conductive material; and
measuring crosstalk between the first signal pattern and the second signal pattern, wherein
each of the first pin and the second pin has a distal end and a proximal end opposite to the distal end,
the distal end of the first pin and the distal end of the second pin are in contact with the first signal pattern and the second signal pattern, respectively,
the shield plate extends along a plane orthogonal to the first direction and has an upper end and a lower end opposite to the upper end in a third direction orthogonal to the first direction and the second direction, the lower end being in contact with the ground pattern,
the shield plate is located between the first pin and the second pin in the first direction, and
the shield plate has a thickness greater than a skin depth for an electromagnetic wave equal in frequency to signals flowing through the first signal pattern and the second signal pattern.

2. The crosstalk measuring method according to claim 1, wherein the upper end is located above the proximal end of the first pin and the proximal end of the second pin in the third direction.

3. The crosstalk measuring method according to claim 1, wherein
the shield plate has a rear end and a front end opposite to the rear end in the second direction, and
the front end is located to protrude in the second direction by 0.5 mm or more and 5 mm or less from the distal end of the first pin and the distal end of the second pin.

4. The crosstalk measuring method according to claim 3, wherein
the shield plate has a plurality of protrusions at the lower end, the plurality of protrusions being arranged at intervals in the second direction and brought into contact with the ground pattern, and
a pitch between two adjacent protrusions among the plurality of protrusions is 0.4 mm or less.

5. The crosstalk measuring method according to claim 4, wherein each of the plurality of protrusions has a height of 0.5 mm or less.

6. A crosstalk measuring probe comprising:
a first pin and a second pin; and
a shield plate made of a conductive material, wherein
each of the first pin and the second pin has a distal end and a proximal end opposite to the distal end,
the distal end of the first pin and the distal end of the second pin are spaced apart from each other in a first direction,
the shield plate extends along a plane orthogonal to the first direction and is located between the first pin and the second pin in the first direction, and
the shield plate has a thickness greater than a skin depth for an electromagnetic wave equal in frequency to signals flowing through the first pin and the second pin.

7. The crosstalk measuring probe according to claim 6, wherein
the shield plate has a rear end and a front end opposite to the rear end in a second direction orthogonal to the first direction, and
the front end is located to protrude in the second direction by 0.5 mm or more and 5 mm or less from the distal end of the first pin and the distal end of the second pin.

8. The crosstalk measuring probe according to claim 7, wherein
the shield plate has an upper end and a lower end opposite to the upper end in a third direction orthogonal to the first direction and the second direction, and
the shield plate has a plurality of protrusions at the lower end, the plurality of protrusions being arranged at intervals in the second direction.

9. The crosstalk measuring probe according to claim 8, wherein a pitch between two adjacent protrusions among the plurality of protrusions is 0.4 mm or less.

10. The crosstalk measuring probe according to claim 8, wherein each of the plurality of protrusions has a height of 0.5 mm or less.

11. The crosstalk measuring probe according to claim 6, wherein
the shield plate has an upper end and a lower end opposite to the upper end in a third direction orthogonal to the first direction and the second direction, and
the upper end is located above the proximal end of the first pin and the proximal end of the second pin in the third direction.
